(19) United States
(12) Patent Application Publication
(10) Pub. No.: US 2025/0391627 A1
(43) Pub. Date: Dec. 25, 2025

(54) GAS CLUSTER ION BEAM APPARATUS

(71) Applicant: IIPT Inc., Tokyo (JP)

(72) Inventors: Katsumi Tokiguchi, Mitaka-shi, Tokyo (JP); Katsumi Hanazono, Mitaka-shi, Tokyo (JP); Izumi Kataoka, Mitaka-shi, Tokyo (JP)

(21) Appl. No.: 18/871,602

(22) PCT Filed: Jun. 13, 2023
(86) PCT No.: PCT/JP2023/021820

§ 371 Date: Sep. 4, 2025

(30) Foreign Application Priority Data
Jun. 22, 2022 (JP) 2022-100208

(51) Int. Cl. H01J 37/08; H01J 37/145

(52) U.S. Cl. CPC H01J 37/08; H01J 37/145; H01J 2237/0473; H01J 2237/0812; H01J 2237/151; H01J 2237/152

(57) ABSTRACT

A GCIB apparatus that can change the energy of ions to be irradiated onto a substrate without changing the electrode arrangement of the GCIB apparatus that have an extraction electrode arrangement optimized for a specific voltage or a permanent magnet type magnet that effectively removes singly charged monomer ions at that voltage, or the magnetic field strength of the permanent magnet type magnet. A separated high voltage power supply that generates a positive or negative high voltage in addition to the first high voltage power supply, the second high voltage power supply and the third high voltage power supply, and a separated high voltage application circuit that applies a positive or a negative separated high voltage supplied from the separated high voltage power supply to the ground electrode of the extraction electrode and the ground electrode portions of the one or more electrostatic lenses.

### TECHNICAL FIELD

The present invention relates to a gas cluster ion beam apparatus.

### BACKGROUND ART

Patent Document 1 and Non-Patent Document 1 disclose a conventional gas cluster ion beam apparatus (hereinafter sometimes referred to as a GCIB apparatus) in which a gas cluster beam is ionized by electron impact in an ionizer to generate gas cluster ions, which are extracted as a beam from the ionizer using an extraction electrode, transported, and irradiated onto a substrate.

### RELATED ART DOCUMENTS

### Patent Document

Patent Document 1: Japanese Patent 6,632,937 (Dec. 20, 2019)

### Non-Patent Document

Non-Patent Document 1: Materials processing by cluster ion beams (Isao Yamada, 2015, CRC Press)

### SUMMARY OF INVENTION

### Technical Problem

In the case of a gas cluster ion beam, if the average energy of each atom/molecule after collision with a substrate is increased, the processing speed of polishing, etching, or the like of the substrate surface tends to increase. In order to increase the processing speed, it is necessary to increase the acceleration voltage (Va) applied to an acceleration electrode provided at the outlet of the ionizer. When the accelerating voltage is high, the current that can be extracted is also generally high. On the other hand, if a gas cluster ion beam extracted at a low acceleration voltage of 10 kV or less is used for irradiation, surface processing (polishing, etching, etc.) can be performed with extremely little damage to the substrate. In either case of using a beam in the high voltage region or the low voltage region, it is important to accomplish a high irradiation current and to arbitrarily control the beam shape in order to improve processing performance. In a gas cluster ion beam (hereinafter sometimes abbreviated as GCIB) apparatus, the current and the shape of an ion beam that can be extracted depending on the shape and the voltage of an extraction electrode. For example, in a system in which the ion extraction performance has been optimized at a certain high acceleration voltage, if attempting to increase the beam energy by just increasing the acceleration voltage, since the distance between the acceleration electrode and the extraction electrode has not been changed, abnormal discharges will be occurred frequently between the acceleration electrode and the extraction electrode so that it makes be difficult for extracting a stable beam. The abnormal discharges can be reduced by increasing the above distance. Normally, when the voltage applied to the acceleration electrode is increased, the distance between the acceleration electrode and the extraction electrode must be increased. On the other hand, when the voltage applied to the accelerating electrode is reduced to a lower voltage while the system is maintained, no abnormal discharge occurs. However, since the extraction electric field strength is insufficient, a problem occurs in which a sufficient extraction current cannot be obtained. It is necessary to reduce the distance between the acceleration electrode and the extraction electrode to increase the extraction current. Furthermore, in order to obtain the maximum current and the optimal beam shape according to the voltage to be used, in conventional apparatuses it was necessary to change the distance between the acceleration electrode and the extraction electrode, and the shape of each electrode for each acceleration voltage to be used. For this reason, in conventional GCIB apparatuses, it was necessary to adjust the distance between the acceleration electrode and the extraction electrode for each voltage while the vessel was exposed to the atmosphere.

In addition, conventional GCIB apparatuses ware required to be equipped with a permanent magnet type magnet that has the magnetic field strength required to remove monoatomic/monomolecular singly charged ions (called monomer ions) depending on the voltage to be used. The singly charged ions (monomer ions) of atoms/molecules that make up the cluster beam travel straight in the absence of the magnetic field after being deflected in the magnetic field. The orbital radius r increases with increasing of the mass number, and the deflection angle decreases with increasing of the mass number. Therefore, when selecting an appropriate value for the magnetic field strength depending on the distance between the magnet and the irradiated substrate, it is possible to prevent the singly charged ions from impinging on the irradiated substrate, and to irradiate only GCIB with a high mass number. For this purpose, the magnetic field strength of the magnet is determined so as to remove the singly charged monomer ions which have a specific voltage. However, since the permanent magnet is used, the magnetic field strength cannot be varied. Therefore, when a permanent magnet type magnet is used, if a beam is extracted with an acceleration voltage higher than the designed voltage, the orbital radius of the monomer ions becomes larger and the deflection angle becomes smaller, which is a problem in that the beam is irradiated onto the irradiated substrate.

As described above, in conventional GCIB apparatuses, in order to obtain the optimum beam current and the beam shape for each acceleration voltage, it was necessary to change the distance between the acceleration electrode and the extraction electrode or to replace from the existing electrodes to the electrodes which have a different shape. It was also necessary to replace the existing permanent magnet type magnet with the other permanent magnet type magnet that have the magnetic field strength depending on the voltage. In order to carry out such a replacement, it is necessary to once expose the vacuum vessel to the atmosphere. However, such exposure to the atmosphere can cause moisture absorption on the surface of the electrode, and there is also a problem in that it takes a longer time to be able to stably apply a high voltage after evacuation. For this reason, there has been a demand for a GCIB apparatus that can maintain the suitable beam current and the beam shape over a wide range of voltage regions, while also being capable of removing the singly charged monomer ions without changing the permanent magnet type magnet.

The object of the present invention is to provide a GCIB apparatus that can change the energy of irradiated ions without changing the electrode arrangement of the GCIB apparatus that have an extraction electrode arrangement optimized for a specific voltage or a permanent magnet type magnet that effectively removes singly charged monomer ions at that voltage, or the magnetic field strength of the permanent magnet type magnet.

### Solution to Problem

The configuration of the present invention for solving the problems will be described below. For easier understandings, the following descriptions will use the same reference numerals as the reference numerals used in the descriptions of the embodiments illustrated in figures. However, these reference numerals should not be used to interpret the present invention as being limited to the embodiments.

A gas cluster ion beam apparatus to which the present invention is subjected comprises a cluster generation chamber 1, a skimmer 4, an ionizer 5, a beam transport system TS and a permanent magnet type magnet 21. The cluster generation chamber 1 generates a neutral gas cluster beam of gas atoms or gas molecules by injecting high-pressure gas through a nozzle 3 in a vacuum. The skimmer 4 skims a cluster beam from a central region in the neutral gas cluster beam. The ionizer 5 generates cluster ions by impacting accelerated thermal electrons with the cluster beam introduced through the skimmer 4. The beam transport system TS extracts the cluster ions from the ionizer 5 as a gas cluster ion beam 11 by the potential difference between an acceleration electrode 6 provided at the outlet of the ionizer 5 and to which a positive high voltage is applied from a high voltage power supply (22a), and an extraction electrode 7 provided downstream of the acceleration electrode 6, and irradiates the gas cluster ion beam 11 onto an irradiated substrate 15 placed in vacuum vessel for an irradiation chamber 12 through one or more electrostatic lenses (9a, 9b) to which the positive high voltage is applied from the high voltage power supplies (22b, 22c). The permanent magnet type magnet 21 included in the beam transport system removes monomer ions. The present invention further comprises a separated high voltage power supply 22d that generates a positive or negative high voltage in addition to the high voltage power supplies (22a, 22b, 22c), and a separated high voltage application circuit 27, 27a that applies the positive or negative high voltage from the separated high voltage power supply 22d to the ground electrode portion of the extraction electrode 7, the ground electrode portion of the one or more electrostatic lenses (9a, 9b) and the negative terminal portions of the first high voltage power supply, the second high voltage power supply and the third high voltage power supply (22a, 22b, 22c).

According to the present invention, in the case that the separated high voltage power supply 22d generates a positive high voltage, when the positive high voltage is applied from the separated high voltage power supply 22d to the ground electrode portion of the extraction electrode 7 and the ground electrode portion of the one or more electrostatic lenses (9a, 9b), the ion beam that is extracted from the ionizer 5 can irradiate as the cluster ion beam onto the irradiated substrate 15 under the same voltage condition as when a positive or negative high voltage that is applied from the separated high voltage power supply 22d is added to a positive high voltage that is applied from the high voltage power supply to the extraction electrode 7 and one or more electrostatic lenses. On the other hand, in the above-mentioned beam transport system TS, the optimum extraction condition in case of applying the original positive voltage is maintained. As a result, it is possible to increase the energy of the irradiated cluster ion beam by using the high voltage to which the positive high voltage applied from the separated high voltage power supply 22d is added without changing the electrode arrangement of the GCIB apparatus and the magnetic field strength of the magnet, without changing the existing equipment.

In the case that the separated high voltage power supply 22d generates a negative high voltage, since the positive high voltage that is applied on the acceleration electrode 6 provided at the outlet of the ionizer 5 is reduced by the amount of the negative voltage that is applied from the separated high voltage power supply 22d, the energy of the cluster ion beam that is irradiated onto the irradiated substrate 15 is similarly reduced by the amount of the negative voltage. However, the beam can be extracted by the original voltage difference (the electric field strength) since the voltage difference at the extraction portion (the portion between the acceleration electrode 6 and the extraction electrode 7) is not changed even if adding the negative voltage, and the extraction performance under the optimum extraction condition is maintained. Therefore, the beam decelerates in the space from the beam transport system TS until the irradiated substrate 15 that is positioned at the ground potential because the beam transport system TS is in a negative voltage. As a result, there is an advantage that a higher current value can be obtained since the extraction performance is optimized though the beam is spread and the irradiated beam current is slightly decreased, comparing to the case that the high voltage in which the negative voltage is decreased is applied to the acceleration electrode 6 provided at the outlet of the ionizer 5 in the conventional apparatus illustrated in FIG. 1.

In addition, according to another aspect of the present invention, the invention may further comprises a separated high voltage power supply 22d that generates a positive or negative high voltage in addition to the high voltage power supplies (22a, 22b, 22c) and a separated high voltage application circuit 27 that applies the positive or negative high voltage from the separated high voltage power supply 22d to a ground electrode portion of an extraction electrode 7 and a ground electrode portion of one or more electrostatic lenses (9a, 9b). In addition, each negative terminal portion of the high voltage power supplies (22a, 22b, 22c) may be grounded. According to the another aspect of the invention comprises the above-mentioned-elements, it is possible to increase the energy of an irradiated cluster ion beam by using the high voltage to which the high voltage applied from the separated high voltage power supply 22d is added without changing electrode arrangement of a GCIB apparatus and the magnetic field strength of the magnet, without changing the existing equipment.

The separated high voltage application circuit 27 may include a common electrode portion 23 to which the ground electrode portion of the extraction electrode 7 at ground potential, the ground electrode portion of the one or more electrostatic lenses (9a, 9b), and the ground electrode portion directly connected to the permanent magnet type magnet are electrically and mechanically connected in common. In case of providing such the common electrode portion 23, it is possible to configure the separated high voltage application circuit 27 with a few components.

The common electrode portion 23 is preferably made of a metal one-piece electrode plate member (23). The electrode plate member preferably has a structure that mechanically supports the extraction electrode 7, the one or more electrostatic lenses (9a, 9b) and the permanent magnet type magnet 21. If the electrode plate member is attached through an insulating glass 24 which is an electrical insulator to a vacuum vessel 2 in which at least the extraction electrode 7, the one or more electrostatic lenses (9a, 9b) and the permanent magnet type magnet 21 are stored, the extraction electrode, the one or more electrostatic lenses and the permanent magnet type magnet can be supported with a mechanically easy and simple structure by using the electrode plate member (23).

As the one or more electrostatic lenses, it is possible to use a structure in which two Einzel lenses are arranged in the direction in which the cluster ion beam passes. In addition, the high voltage power supply may include a first high voltage power supply 22a that applies the high voltage to the acceleration electrode 6, and a second high voltage power supply 22b and a third high voltage power supply 22c that apply high voltages to the two Einzel lenses 9a, 9b constituting the one or more electrostatic lenses. The permanent magnet type magnet 21 may be disposed between the two Einzel lenses 9a, 9b. Therefore, the two Einzel lenses 9a, 9b have two cylindrical ground electrodes at both ends of a central cylindrical electrode (a positive electrode) E3. The positive high voltage applied from the above-mentioned separated high voltage power supply is applied to the two cylindrical ground electrodes when using the above-mentioned one or more electrostatic lenses.

Furthermore, the acceleration electrode 6 may be electrically coupled to a conductive case 51 of the ionizer 5 fixed to a first electrical connection member La which is electrically coupled to a first high voltage introduction flange 20a attached to the vacuum vessel 2. Only the central cylindrical electrode E3 of the two Einzel lenses may be coupled to a second electrical connection member Lb and a third electrical connection member Lc which are electrically coupled to a second high voltage introduction flange 20b and a third high voltage introduction flange 20c attached to the vacuum vessel 2. The first electrical connection member La, the second electrical connection member Lb and the third electrical connection member Lc are preferably each made of a metallic rod member. In the case mentioned above, there are advantages that one or more insulating glasses which are mechanically constituting one or more Einzel lenses 9a, 9b are not required and it is easier to supply power to the central cylindrical electrode E3, in addition that it is easy to provide the permanent magnet type magnet.

Each of metallic shielding members 26a, 26b and 26c, which prevent the charged particles generated from the gas cluster ion beam 11 from reaching the first high voltage introduction flange 20a, the second high voltage introduction flange 20b and the third high voltage introduction flange 20c, may be fixed to each of the three metallic rod members 25 that constitute the first electrical connection member La, the second electrical connection member Lb and the third electrical connection member Lc. Providing the metallic shielding members 26a, 26b and 26c makes it possible to prevent micro-discharges between the metal rod member 25 and the inner surface of the vacuum vessel 2 (specifically, the edge portion E) close to the metal rod member 25 from occurring. As a result, the extracted gas cluster ion beam is stable.

Each of the shielding members 26a, 26b and 26c may have a curved shape of which a center is fixed to the metallic rod member 25 and that curves from the center toward the outside, so as to approach the corresponding high voltage introduction flange. The case that adopts the shape mentioned above makes it possible to effectively prevent the charged particles that induce micro-discharges from penetrating into the shielding members 26a, 26b and 26c.

The separated high voltage power supply 22d may be a bipolar high voltage power supply that can generate both positive and negative outputs. As a result, the case mentioned above has the advantage that the irradiation with high voltage and the irradiation with low voltage can be performed on the same irradiated substrate without breaking the vacuum, simplifying the irradiation process.

Furthermore, a central magnetic field strength of the permanent magnet type magnet 21 may be a value of 0.1 T or more, which causes a deflection to such an extent that SF₆ monomer ions in the gas cluster beam containing SF₆ extracted from the ionizer at an acceleration voltage of 30 KV do not reach the irradiated substrate. The removal performance of monomer ions varies depending on the magnet strength and the linear distance from the magnet to the irradiated substrate 15. In a practical apparatus, the linear distance from the magnet to the irradiated substrate is about 10 to 60 cm. For this linear distance, if the magnetic field strength of the magnet is about 0.1 T, since the magnetic field strength increases in proportion to the distance between the magnetic poles as the distance between the magnetic poles is reduced, there is the advantage that monomer ions can be easily removed regardless of the linear distance of 10 to 60 cm.

In a specific aspect of the invention, it is preferable that the output voltages of the high voltage power supplies 22a, 22b and 22c and the output voltage of the separated high voltage power supply 22d may be equal, when the high voltage power supplies 22a, 22b and 22c output a positive voltage and the separated high voltage power supply 22d applies the positive high voltage. In addition, it is preferable that the output voltages of the high voltage power supplies 22a, 22b and 22c may be higher than the output voltage of the separated high voltage power supply 22d, when the high voltage power supplies 22a, 22b and 22c output a positive voltage and the separated high voltage power supply 22d applies the positive high voltage.

### BRIEF DESCRIPTION OF DRAWINGS

FIG. 1 is a diagram used to explain the configuration of a GCIB apparatus previously developed by the inventors, which is the subject of improvement of the present invention.

FIG. 2 is a diagram used to explain the configuration of an example of the first embodiment of a GCIB apparatus of the present invention.

FIG. 3 is a diagram used to explain the configuration of the second embodiment of the GCIB apparatus of the present invention.

FIG. 4 is a diagram used to explain the configuration of the third embodiment of the GCIB apparatus of the present invention.

FIG. 5 is a diagram used to explain the configuration of the fourth embodiment of the GCIB apparatus of the present invention.

### DESCRIPTION OF EMBODIMENTS

### [Conventional GCIB Apparatus]

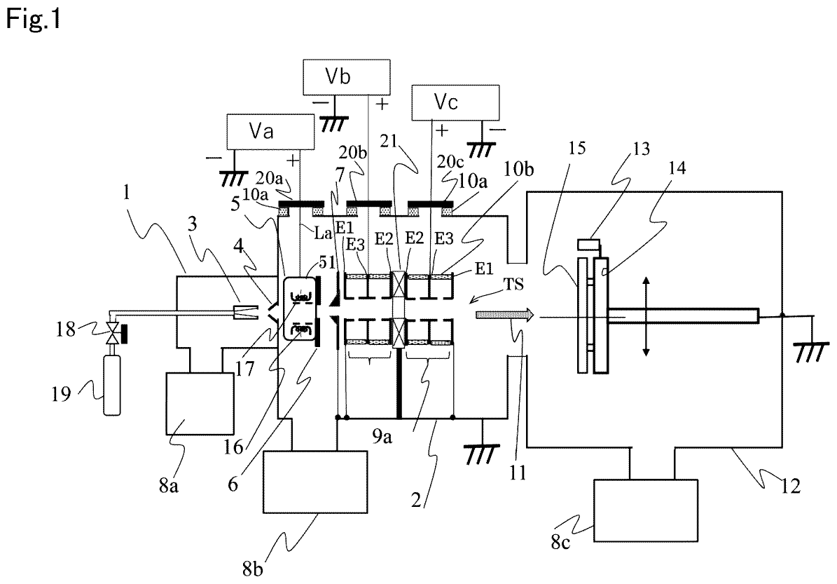

FIG. 1 is a diagram used to explain the configuration of a gas cluster ion beam apparatus (GCIB apparatus) previously developed by the inventors of the present invention, which is the subject of improvement of the present invention. In FIG. 1, reference numerals are used as follows. 1 denotes a cluster generation chamber, 2 denotes a vacuum vessel, 3 denotes a nozzle, 4 denotes a skimmer, 5 denotes an ionizer, 6 denotes an acceleration electrode, 7 denotes an extraction electrode, 8a, 8b and 8c denote vacuum exhaust pumps, 9a and 9b denote first Einzel lens and second Einzel lens that constitute electrostatic lenses, 12 denotes a vacuum vessel for an irradiation chamber. 13 denotes a Faraday cup, 14 denotes a stage for an irradiated substrate, 15 denotes an irradiated substrate, 16 denotes a tungsten thermal filament, 17 denotes an anode rod, 19 denotes a high-pressure gas cylinder, 21 denotes a permanent magnet type magnet, and 22a, 22b and 22c denote first high voltage power supply, second high voltage power supply and third high voltage power supply.

In the GCIB apparatus which is the subject of improvement illustrated in FIG. 1, when SF₆ gas which is introduced from the high-pressure gas cylinder 19 to the nozzle 3 is ejected from the nozzle 3, condensation of atoms and molecules occurs due to adiabatic expansion so that a neutral gas cluster beam is formed. Thereafter, only the neutral gas cluster beam that is high-density and is positioned at the center portion is skimmed as a cluster beam by the skimmer 4 and then the neutral gas cluster beam is introduced into an ionization chamber of the ionizer 5. In the ionizer 5, thermal electrons generated from the tungsten thermal filament 16 are accelerated to several hundreds of eV, which is corresponding to the voltage applied to the anode rod 17, and collide with the neutral cluster beam causing ionization. Therefore, the neutral gas cluster beam is efficiently ionized.

Note that a first electrical connection member La, that is electrically connected to a first high voltage introduction flange 20a which is attached to the vacuum vessel 2, is fixed to a conductive case 51 of the ionizer 5. In addition, the acceleration electrode 6 is fixed to the outlet of the conductive case 51, and the acceleration electrode 6 is electrically coupled to the conductive case 51.

Next, a voltage of several tens of kV (Va in the figure) is applied to the acceleration electrode 6 from the first high voltage power supply 22a through the first high voltage introduction flange 20a, the first electrical connecting member La and the conductive case 51. The cluster ions are extracted from the outlet of the ionizer 5 as an ion beam due to the voltage difference (=the electric field strength) between the acceleration electrode 6 to which a high voltage is applied and the extraction electrode 7 at ground potential. Then, the ion beam is transported in the first electrostatic lens 9a and the second electrostatic lens 9b that are comprised of Einzel lenses which are included in the beam transport system TS. The first electrostatic lens 9a and the second electrostatic lens 9b that are comprised of Einzel lenses have cylindrical ground electrode portions E1 and E2 at both ends of the lenses, respectively. Positive high voltages Vb and Vc are respectively applied to central cylindrical electrodes E3 of the first electrostatic lens 9a and the second electrostatic lens 9b from the second high voltage power supply 22b and the third high voltage power supply 22c. In the first electrostatic lens 9a and the second electrostatic lens and 9b, only the cylindrical electrode E3 is coupled to the high voltage introduction flanges 20a and 20b that are attached with the vacuum vessel 2. Note that the high voltage introduction flanges 20a, 20b and 20c are fixed to the vacuum vessel 2 via an insulating glass 10a.

The permanent magnet type magnet 21 at ground potential is mounted between the first electrostatic lens 9a and the second electrostatic lens 9b in the beam transport system TS. The magnet 21 deflects and removes monoatomic or monomolecular singly charged ions (hereinafter referred to monomer ions) included in the gas cluster ion beam 11, so as to prevent the monomer ions from reaching onto the irradiated substrate 15. The magnet 21 that removes the monomer ions within the beam transport system TS from the ionizer 5 until the irradiated substrate 15 is a specific configuration for the gas cluster ion beam apparatus.

The irradiated substrate 15 is positioned in a state that the irradiated substrate 15 is attached to the stage for the irradiated substrate 14 in the vacuum vessel for an irradiation chamber 12. Then the irradiation of the gas cluster ion beam 11 is carried out onto the irradiated substrate 15. The Faraday cup 13 measures the current value of the gas cluster ion beam 11. The Faraday cup current which is measured by the Faraday cup is measured by an ammeter (not illustrated) which is placed outside of the vacuum vessel for an irradiation chamber 12 through an electric cable. When the current value is measured, the stage for the irradiated substrate 14 moves in the direction of the arrow in the figure, the Faraday cup 13 moves to a position where the axis of the Faraday cup 13 and the gas cluster ion beam 11 coincide, and the measurement of the current value of the gas cluster ion beam 11 is carried out.

In FIG. 1, the energy (eV) of the gas cluster ion beam 11 that is irradiated onto the irradiated substrate 15 at ground potential is the value of the voltage (Va, several kV to several tens of kV) which is applied to the ionizer 5 (the acceleration electrode 6) multiplied by the ions valence (usually singly charged). However, when the gas cluster ion beam 11 is irradiated onto the irradiated substrate 15, atoms or molecules that constitute the gas cluster ion beam 11 break apart, spread in the surface direction and etch on the irradiated substrate 15, causing so-called lateral sputtering phenomenon. The average energy per one atom or one molecule that is formed by dissociation of the gas cluster ion beam 11 is the value of the above-mentioned energy of the gas cluster ion beam divided by the cluster size (number), and is the value in the range of several eV to several tens of eV (several V to several tens of V in voltage conversion). Therefore, the apparatus of the present embodiment can carry out surface processing that causes less damage to a surface structure of the irradiated substrate, compared to a general-purpose ion beam processing apparatus that performs surface processing by accelerating singly charged ions to several kV. Furthermore, in case of substrate processing (etching, etc.) using the beam of a typical ion beam processing apparatus, processing in the vertical direction on the surface of the substrate is mainly performed. In the case of the processing using the gas cluster ion beam to be compared with the above-mentioned processing, since utilizing the feature of the so-called lateral sputtering phenomenon that atoms or molecules broken apart, spread in the horizontal surface direction and etch on the irradiated substrate as mentioned above, the processing has an advantage of achieving the excellent processing performance for surface flattening.

Note that it must be required to extract ions directly from the ion source at a voltage of several volts to several tens of volts that corresponds to the energy of the ions, in order to obtain a beam of several eV to several tens of eV per one ion using a general-purpose ion beam processing apparatus that uses singly charged ions. On the other hand, in case of a general-purpose ion beam processing apparatus, the ion source, generally, that extracts ions from a plasma source are used. However, since the extraction voltage is insufficient with such a low voltage, the plasma is merely ejected without forming an ion beam so that high-current ion beam cannot be extracted.

By the way, in the case of a conventional gas cluster ion beam apparatus, the ion beam is extracted by using both the acceleration electrode 6 that is mounted on the ionizer and the extraction electrode 7 that is provided at the downstream of the acceleration electrode 6. The energy of the ions that are extracted is several keV to several tens of keV that is depending on the voltage of several kV to several tens of kV which is applied to the acceleration electrode 6. Therefore, the current which is extracted can be also high so that the irradiated ion current which is irradiated onto the irradiated substrate 15 is at the level of several tens of μA to hundreds of μA. Since the cluster size is on average several hundred particles to several thousand particles, the numbers of dissociated particles after collision with the surface are several mA to hundred mA. Therefore, the energy of a unit atom small at several tens of eV, but the current value equivalent or greater than the current value of a general-purpose ion beam processing apparatus that extracts singly charged ions at the extraction voltage of several kV can be obtained. Accordingly, the surface of the substrate can be etched at high speed.

However, in order to obtain the maximum current and the optimized beam shape corresponding to the voltage to be used, it was required that the distance between the acceleration electrode 6 and the extraction electrode 7 or the shape of the acceleration electrode 6 and the extraction electrode 7 was changed for each acceleration voltage to be used in the GCIB apparatus illustrated in FIG. 1. Therefore, it was necessary to carry out to adjust the distance between the acceleration electrode 6 and the extraction electrode 7 for each voltage to be used while the vessel was exposed to the atmosphere.

In addition, in order to extract a beam at a different acceleration voltage in the GCIB apparatus illustrated in FIG. 1, it is necessary that the permanent magnet type magnet 21 which has a sufficient magnet field strength to remove monoatomic/monomolecular singly charged ions (referred to monomer ions) depending on the voltage to be used is equipped. The singly charged ions (monomer ions) of atoms/molecules that make up the cluster ion beam travel straight in the absence of the magnetic field after being deflected in the magnetic field space. The orbital radius r of the ion beam in the permanent magnet type magnet 21 increases with increasing the mass number, and the deflection angle decreases with increasing of the mass number. Therefore, when selecting an appropriate value for the magnetic field strength depending on the distance between the magnet 21 and the irradiated substrate 15, it is possible to prevent the singly charged ions from impinging on the substrate, and to irradiate only GCIB with a high mass number. The magnetic field strength of the magnet 21 is determined so as to remove the singly charged monomer ions which have a specific voltage. However, since the permanent magnet is used as the magnet 21, the magnetic field strength cannot be varied. Therefore, when the magnet 21 is used, if a beam is extracted with an acceleration voltage higher than the designed voltage, the orbital radius of the monomer ions becomes larger and the deflection angle becomes smaller, which is a problem in that the beam is irradiated onto the irradiated substrate 15.

Accordingly, in the GCIB apparatus illustrated in FIG. 1, in order to obtain the optimum beam current and the beam shape for each acceleration voltage, it was necessary to change the distance between the acceleration electrode 6 and the extraction electrode 7 or to replace from the electrodes which have the existing shape to the electrodes which have a different shape. It was also necessary to replace from the existing magnet to the permanent magnet type magnet 21 that have the magnet field strength which varies depending on the voltage. Although it is necessary to once expose the vacuum vessel 2 to the atmosphere in order to carry out such a replacement, since such exposure to the atmosphere can cause moisture absorption on the surface of the electrode, there is also a problem in that it takes a longer time to be able to stably apply a high voltage after evacuation. For this reason, there has been a demand for a GCIB apparatus that can maintain the suitable beam current and the beam shape over a wide range of voltage regions, while also being capable of removing the singly charged monomer ions without changing the permanent magnet type magnet 21.

### First Embodiment

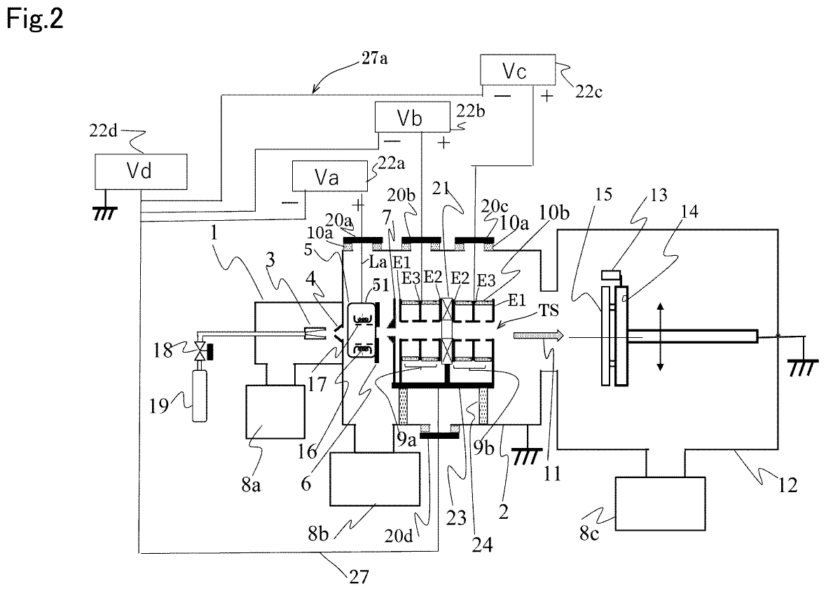

FIG. 2 is a diagram illustrating a configuration of an example of an embodiment of the GCIB apparatus based on the present invention for resolving the above-mentioned problem of the conventional GCIB apparatus illustrated in FIG. 1. In this embodiment, components similar to those of the conventional GCIB apparatus shown in FIG. 1 are denoted by the same reference numerals as those in FIG. 1. The GCIB apparatus of the present embodiment also generates a cluster beam of gas atoms or gas molecules by injecting high-pressure gas through a nozzle 3 in a vacuum, and also introduces a beam from a cluster beam being in a central region to the ionizer 5 through a skimmer 4. An ionizer 5 generates cluster ions by impacting accelerated thermal electrons with the cluster beam. Then, the ions are extracted from the ionizer 5 as a cluster ion beam by an acceleration electrode 6 provided at the outlet of the ionizer 5 and to which a positive high voltage is applied, and an extraction electrode 7 provided downstream of the acceleration electrode 6. In a state where a positive high voltage is applied from a first high voltage power supply 22a, a second high voltage power supply 22b and a third high voltage power supply 22c to the extraction electrode 7 and the one or more electrostatic lenses 9a, 9b, the gas cluster ion beam 11 is irradiated onto an irradiated substrate 15 placed in a vacuum vessel 12 for an irradiation chamber through the beam transport system TS including electrostatic lenses 9a, 9b and a permanent magnet type magnet 21. The present embodiment comprises a separated high voltage power supply 22d that generates a positive high voltage in addition to the first high voltage power supply 22a, the second high voltage power supply 22b and the third high voltage power supply 22c, and a separated high voltage application circuit 27 that applies the separated high voltage supplied from the separated high voltage power supply 22d to a common electrode portion 23 and the ground electrode portions of the one or more electrostatic lenses 9a, 9b. The common electrode portion 23 comprises an electrode plate member made of a metal plate and provides a ground electrode portion of the extraction electrode 7. In the present embodiment, the separated high voltage application circuit 27 includes circuit portions 27a that respectively couples the negative terminal portions of the first high voltage power supply 22a, the second high voltage power supply 22b and the third high voltage power supply 22c to the positive electrode portion of the separated high voltage power supply 22d. In the present embodiment, the separated high voltage application circuit 27 is connected to the common electrode portion 23 to which the ground electrode portion of the extraction electrode 7, cylindrical ground electrode portions E1 and E2 other than the central positive electrode which constitutes the electrostatic lenses and the ground electrode portion of the magnet 21 are electrically or mechanically connected in common. The common electrode portion 23 is made of a metal one-piece electrode plate member. The common electrode portion 23 made of the electrode plate member has a structure that mechanically supports the extraction electrode 7, the electrostatic lenses 9a, 9b and the permanent magnet type magnet 21. Since the common electrode portion 23 made of the electrode plate member is attached through an insulating glass 24 which is an electrical insulator to a vacuum vessel 2 in which the extraction electrode 7, the electrostatic lenses 9a, 9b and the permanent magnet type magnet 21 are stored, the extraction electrode 7, the electrostatic lenses 9a, 9b and the permanent magnet type magnet 21 can be supported with a mechanically easy and simple structure by using the common electrode portion 23. Such common electrode portion 23 simplifies a construction of the separated high voltage application circuit 27 with a few components.

In the present embodiment, the positive high voltage generated from the separated high voltage power supply 22d is applied to the ground electrode portion of the extraction electrode 7 and the two ground electrodes E1 and E2 at both ends of the central cylindrical electrode E3 (a positive electrode) of the electrostatic lenses 9a, 9b. In the structure mentioned above, the ion beam extracted from the ionizer 5 is irradiated onto the irradiated substrate 15 as a beam generated under the same voltage condition as when a positive high voltage applied from the separated high voltage power supply 22d is added to a positive high voltage applied from the first high voltage power supply 22a, the second high voltage power supply 22b and the third high voltage power supply 22c to the extraction electrode 7 and the electrostatic lenses 9a, 9b. As the result, it is possible to increase the energy of the irradiated ion by using the high voltage to which the positive high voltage applied from the separated high voltage power supply 22d is added without changing the electrode arrangement of the GCIB apparatus and the magnetic field strength of the magnet 21 and without changing the existing equipment.

In the present embodiment, when the output generated from the separated high voltage power supply 22d is applied to the electrode plate member which constitutes the common electrode portion 23, if a value of the voltage of the separated high voltage power supply 22d is +Vd, a value of the voltage of the ionizer 5 is Vd+Va with respect to the ground potential. On the other hand, since the extraction electrode 7 is biased by Vd in the extraction region, the potential difference between the acceleration electrode 6 and the extraction electrode 7 is maintained at Va. In addition, since a potential of the irradiated substrate 15 is at the ground potential, the gas cluster ion beam 11 in FIG. 2 is irradiated onto the irradiated substrate 15 by the energy corresponding to the voltage of Vd+Va. On the other hand, since the beam transport system TS constituted by the electrostatic lenses 9a, 9b and the permanent magnet type magnet 21 is also biased by Vd, the singly charged ions are subjected to the magnet field deflection which is corresponding to the energy depending on the voltage Va. Therefore, the orbital radius r is not varied, and the feature of removing the singly charged monoatomic/monomolecular ions (monomer ions) is maintained as same as the feature in conventional situation. Therefore, according to the present embodiment, it is possible to increase the ion energy flowing into the irradiated substrate 15 while the performance of the optimized beamline is maintained at the acceleration voltage of Va.

In the present embodiment, the voltage Vd applied from the separated high voltage power supply 22d is a positive high voltage as described above, but the voltage Vd may be a negative high voltage (−Vd). In this way, it is possible to reduce the irradiated energy to Va−Vd without changing the performance of the beam extraction at a positive high voltage Vd. In the case that the separated high voltage power supply 22d outputs a negative high voltage, since the positive high voltage applied to the conductive case 51 of the ionizer 5 is reduced by only the amount of the negative voltage which is applied from the separated high voltage power supply 22d, the energy of the ion beam irradiated onto the irradiated substrate 15 is also reduced by only the amount of the negative voltage. However, since the voltage difference of the extraction portion (a portion between the acceleration electrode 6 and the extraction electrode 7) is not changed even if adding a negative voltage, the beam can be extracted with the original voltage difference (an electric field strength), and the performance of the extraction under the optimized extraction conditions is maintained. In the case mentioned above, since the beam transport system is at a negative voltage, the speed of the beam is reduced in the space from the beam transport system to the irradiated substrate 15 at the ground potential. As a result, the beam is spread and the irradiated beam current tends to slightly reduced. However, since the performance of the extraction is optimized, there is an advantage that a higher current can be obtained compared to when a high voltage reduced by the negative voltage is applied to the conductive case 51 of the ionizer 5. The configuration mentioned above can be realized because the permanent magnet type magnet 21 is provided at the center between the first electrostatic lens 9a and the second electrostatic lens 9b, and the permanent magnet type magnet 21 with the first electrostatic lens 9a and the second electrostatic lens 9b can be provided on the insulated common electrode portion 23.

Next, a first example in which the embodiment illustrated in FIG. 2 is actually realized will be explained. The first example used an ion beam generated by argon gas or argon gas which is including sulfur hexafluoride (SF₆) gas as a kind of a gas cluster ion beam. A DC voltage applied from the high voltage power supply 22a that has a maximum output voltage of 30 kV was applied to the conductive case 51 of the ionizer 5. A voltage of 30 kV applied from the separated high voltage power supply 22d was applied to the first high voltage power supply 22a. As a result, the energy of gas cluster ions which irradiates onto the irradiated substrate 15 was a level of 60 keV which is corresponding to a voltage of 60 kV. The tungsten thermal filament 16 provided in the ionizer 5 was heated until the sufficient temperature which thermal electrons are sufficiently emitted by heated up with electricity. A DC voltage of several hundreds of V was applied to the space between the tungsten thermal filament 16 and the anode rod 17, and the cluster beam was ionized by acceleration of thermal electrons. The extraction electrode 7 which has a mountain-shaped vertical cross sectioned shape as illustrated in the figure in order to efficiently extract a gas cluster ion beam was used. Furthermore, the extraction electrode 7 was directly fixed with the metal plate which is constituting the common electrode 23. The distance between the acceleration electrode 6 and the extraction electrode 7 was about 10 mm. In case of the distance, the operation at 30 kV provided the largest current and the smallest discharge in interelectrode.

The first electrostatic lens 9a and the second electrostatic lens 9B are respectively made up of a cylindrical Eizel lens configuration. The Einzel lens includes a cylindrical electrode made of stainless. The permanent magnet type magnet 21 to be used was two poles (a dipole) magnet in which N pole and S pole of the permanent magnet are arranged as facing each other. Specifically, a dipole magnet with a central magnetic field of 0.1 T (tesla) or more is used. The magnetic field strength was a value of the magnetic field strength that would obtain the deflection angle in which the singly charged SF₆ monomolecular monomer ions (SF₆⁺) at 30 kV would not irradiate onto the irradiated substrate 15. If an argon cluster beam passes through the magnet mentioned above, since the mass number of argon monomer ions (Ar⁺) is lower than the mass number of SF₆ monomer ions, the deflection radius in the magnetic field becomes smaller so that the deflection angle is bigger and the argon cluster beam would not strike onto the substrate. The removal of monomer ions is confirmed by so-called time-of-flight mass spectrometry. Next, the voltage of +30 kV is applied from the separated high voltage power supply 22d to the metal plate used for the common electrode 23. Therefore, the optimized extraction condition at 30 kV is maintained between the acceleration electrode 6 and the extraction electrode 7. Next, the voltages Vb, Vc that apply to the central cylindrical electrode E3 of the electrostatic lenses 9a, 9b were applied as the optimized voltage when extracting at 30 kV from the high voltage power supplies 22b, 22c. Furthermore, the negative electrode terminals of the high voltage power supplies 22b, 22c were coupled to the output terminals of +30 kV of the separated high voltage power supply 22d. Note that if a value of the voltage Vd of the separated high voltage power supply 22d is set to OV in the state mentioned above, it would be clear to achieve the same extraction condition and the sane transport condition as the example illustrated in FIG. 1.

First of all, the voltage Vd applied from the separated high voltage power supply 22d was set to OV to emit a beam, the Faraday cup 13 which has an opening diameter of 35 mm and is provided in the irradiation chamber vacuum vessel 12 was moved to face the beam. The electrical wire coupled to the Faraday cup 13 was wired to the outside of the vacuumed space, and the ion current was measured by an ammeter (not illustrated in FIG. 2). When the voltages Vb, Vc applied to the central cylindrical electrode E3 of the one or more electrostatic lenses 9a, 9b was adjusted, the current of 100 μA or more was obtained in Ar-GCIB as the Faraday cup current. In the case that the voltage Vd of the separated high voltage power supply 22d was set to 30 kV in the state mentioned above, the current of the same level at 100 μA or more was measured as the value of the Faraday cup current without generating discharge or the like between the acceleration electrode 6 and the extraction electrode 7. In the above-mentioned case, the energy of the cluster ion beam was 60 keV. In addition, when a beam was stationarily irradiated onto the Si substrate with a SiO₂ film, and an irradiation mark was observed, the irradiation mark was the shape with about 3 to 5 mm in diameter. Since the irradiation mark at 30 kV alone (Vd=0 kV) was the shape with 5 to 10 mm in diameter, it was confirmed that the beam convergence was also effective. This is probably because the beam divergence from the second-stage electrostatic lens 9b to the irradiated substrate 15 was restrained by increasing the energy from 30 keV to 60 keV. Similarly, in tests using a gas containing SF₆, the value of the Faraday cup current at 30 kV alone (Vd=0 kV) was compared with the value of the Faraday cup current in case of adding Vd=30 kV to 30 kV alone (Vd=0 kV), and it was confirmed that both results obtained almost the same values of the current of 200 μA or more.

Note that it was confirmed that the gas cluster ion beam that monomer ions were not included with the value of the higher current was obtained even if using the gas species which are forming clusters [for example, NF₃, CF₄, O₂, CO₂ gas and gases which is combining the above-mentioned gases with rare gases (Ar, He or the like)] according to the tests conducted by the inventors though Ar gas or SF₆ gas was used as the gas for GCIB in the example. In the case mentioned above, since the magnetic field strength of the permanent magnet type magnet 21 is set to the value that monomer ions of SF₆ can be deflected and removed (>0.1 T), the gas cluster ion beam which does not include monomer ions is obtained even if the above-mentioned gas species which has a lower molecular mass number than the molecular mass number of SF₆ is used. This is because the magnet is designed with the value of the magnetic field strength in which the SF₆ monomer ions can be removed, so that the orbital radius of ions of the gas species which have a lower mass number than the mass number of SF₆ becomes smaller than the orbital radius of SF₆ monomer ions, and the deflection angle of the ions at the outlet of the magnet becomes larger. Therefore, the orbit after leaving the magnet deviates significantly from the straight beam path, and the monomer ions of the above-mentioned gas species cannot reach the irradiated substrate. Note that the Faraday cup current value of the gas species other than Ar gas and SF₆ gas varies depending on the degree to which each gas is susceptible to clustering and ionization efficiency.

In the second example, a high voltage power supply that generates a negative voltage was used for the separated high voltage power supply 22d illustrated in FIG. 2. The operating conditions other than the conditions explained above were sane as the conditions in the first example. That is, the value of the voltage Va was set to 30 kV, and the value of the voltage Vd in the separated high voltage power supply 22d was set to −10 kV as the operating conditions. In this case, the potential of the conductive case 51 of the ionizer 5 was set to 20 kV with respect to the ground potential which is the potential of the irradiated substrate 15. In the sane state that the current of the Ar-GCIB applied to the Faraday cup 13 was measured, the current value of approximately 100 μA was obtained. As understood from the above, it was clear that the performance at 30 kV alone was maintained with respect to the beam extraction and the transport efficiency. In the observation for the irradiation mark using Ar-GCIB, in the case that Vd=−10 kV, the irradiation mark was about 10-15 mm since the diameter of the beam irradiation mark was slightly spread which is comparing to the case that Vd=0 kV. This is because the beam divergence effect increased due to the lower energy. It is considered that the beam divergence effect mainly worked in the space from the second electrostatic lens 9b until the irradiated substrate 15. In fact, when the state (Vd=−10 kV) was maintained, and the voltages Vb and Vc of the first electrostatic lens 9a and the second electrostatic lens 9b were adjusted, the diameter of the beam irradiation mark was reduced to about 8 mm. Note that even if a bipolar high voltage power supply that can switch between a positive voltage and a negative voltage, and generate both a positive voltage and a negative voltage, as the separated high voltage power supply 22d is used, it was easy to switch between the positive only high voltage power supply and the negative only high voltage power supply both mentioned above.

### Second Embodiment

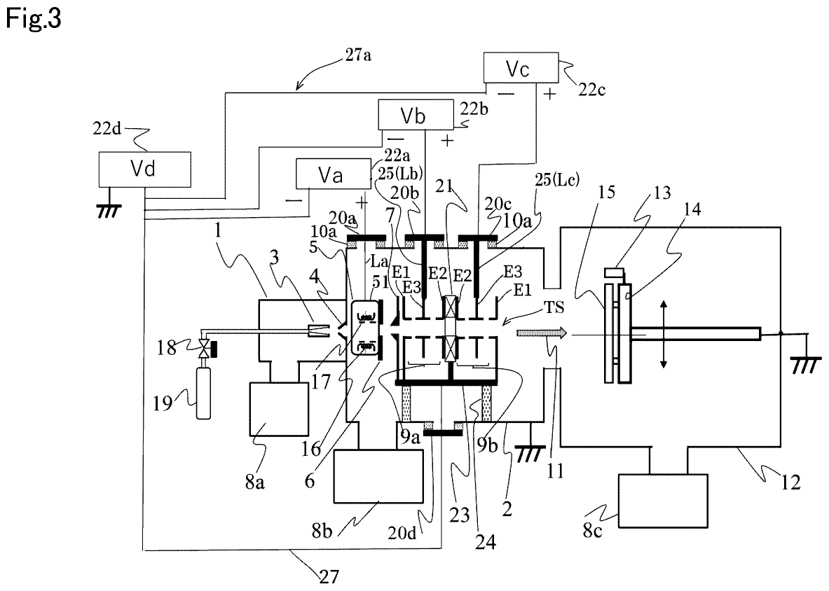

FIG. 3 is a diagram that illustrates a configuration of the second embodiment of the present invention. The present embodiment uses same reference numerals as used in FIG. 1 and FIG. 2 for the components which are same or similar to the components used for the conventional GCIB apparatus illustrated in FIG. 1 and are same or similar to the components used for the first embodiment illustrated in FIG. 2. The present embodiment is also configured that the ground electrode portions E1 provided at was both ends of the electrostatic lens 9a and the electrostatic lens 9b are directly fixed on the common electrode portion 23, and the electrode portions E2 on the opposite sides to the ground electrode portions E1 are fixed on the magnet 21 as same as the first embodiment illustrated in FIG. 2. However, a second electrical connection member Lb and a third electrical connection member Lc that electrically couple the central cylindrical electrode E3 which constitutes the first electrostatic lens 9a and the second electrostatic lens 9b to high voltage introduction flanges 20b, 20c are constituted by a metal rod portion 25 in the present embodiment. That is, the first electrostatic lens 9a and the second electrostatic lens 9b can be fixed on the high voltage introduction flanges 20b, 20c by the second electrical connection member Lb and the third electrical connection member Lc made of the metal rod members 25. In this case, insulating glasses 10b are not entirely required in this embodiment, compared with the embodiment illustrated in FIG. 2. Therefore, since the discharge between the electrodes (creeping discharge) through the insulating glasses 10b does not occur, the operation of the electrostatic lenses is stable, so that it would be realized that a stable lens action is maintained and a beam current is stable.

Note that an example generated a beam with Va=30 kV and Vd=30 kV in the configuration illustrated in FIG. 3. In the extraction from GCIB containing an Ar-CIB and SF₆ gas, since the creeping discharge due to the installed insulating glasses inside the electrostatic lenses does not occur, a stable beam was extracted without generating a discharge or the like for over several hundred hours. When the lens system including the insulating glasses is used, the dirt adhered on the surface of the insulating glasses due to the beam which is sputtering to the metal portion. As a result, discharge will occur several times per hour after 100 hours. In this case, an unstable condition of the high voltage power supply or the like increased due to the inducement by the discharge, resulting in occasional current extraction failure. In the present embodiment, not only there is no discharge generated, but there is no change in the current performance or beam shape, and stable operation for a long period of time is possible, and the effect of the stable operation is also extremely great in a practical use.

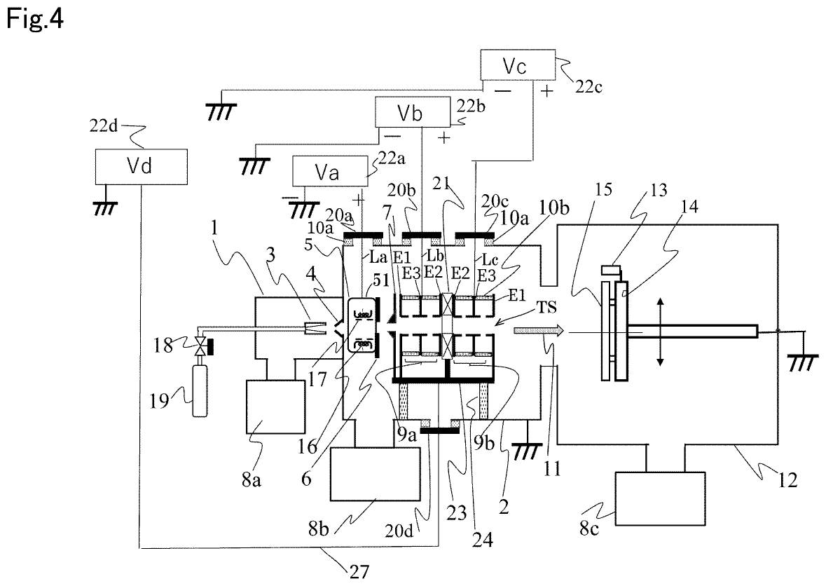

FIG. 4 is a diagram that illustrates a configuration of the third embodiment of the present invention. The present embodiment also uses same reference numerals as used in FIG. 1 and FIG. 2 for the components which are same or similar to the components used for the conventional GCIB apparatus illustrated in FIG. 1 and are same and similar to the components used for the first embodiment illustrated in FIG. 2. Although the first embodiment illustrated in FIG. 2 included the circuit portion 27a that the separated high voltage application circuit 27 respectively coupled the negative terminal portions of the first high voltage power supply 22a, the second high voltage power supply 22b and the third high voltage power supply 22c to the positive terminal portions of the separated high voltage power supply 22d, in the present embodiment, all of the negative terminal portions of the first high voltage power supply 22a, the second high voltage power supply 22b and the third high voltage power supply 22c are grounded. In the present embodiment, the separated high voltage power supply 22d is coupled only to the common electrode portion 23 of the beam transport system TS. Furthermore, the output voltage Vb of the second high voltage power supply 22b alone and the output voltage Vc of the third high voltage power supply 22c alone are respectively supplied to the cylindrical electrode E3. The separated high voltage power supply 22d in this system is coupled only to the common electrode portion 23. In the case mentioned above, when the voltage Vd of the separated high voltage power supply 22d is set to 30 kV, if the power supply that the maximum output voltages Va, Vb and Vc as the first high voltage power supply 22a, the second high voltage power supply 22b and the third high voltage power supply 22c is set to 60 kV is used, each voltage value is same to each value of the first embodiment and the second embodiment.

In the third embodiment illustrated in FIG. 4, the configuration that the voltage Vb and the voltage Vc with respect to the ground potential are directly applied to the cylindrical electrode E3 (anode) is same as the conventional configuration illustrated in FIG. 1. However, as same as the configurations of the first embodiment and the second embodiment respectively illustrated in FIG. 2 and FIG. 3 in the third embodiment illustrated in FIG. 4, the configuration that the positive voltage Vd generated from the separated high voltage power supply 22d is applied to the extraction electrode 7 is differ from the configuration illustrated in FIG. 1. In addition, the configuration that the positive voltage Vd generated from the separated high voltage power supply 22d can be applied to the ground electrode portion E1 of the electrostatic lens 9a and the ground electrode portion E2 of the electrostatic lens 9b is differ from the configuration illustrated in FIG. 1.

In the conventional example illustrated in FIG. 1, the energy of the cluster beam extracted by using the extraction electrode 7 at a ground potential is the energy which corresponds to the voltage Va applied by the first high voltage power supply 22a. For example, when the voltage of the first high voltage power supply 22a is set to 60 kV, the energy of the cluster beam would be 60 keV. In addition, the extracted cluster beam travels through an environment which is generally kept at a ground potential within the electrostatic lenses 9a and 9b, except for the cylindrical electrode E3 that serves as the anode located at the center. As a result, the cluster beam as a 60 keV beam is acted by the electrostatic lenses 9a, 9b. Therefore, the voltage Vb and the voltage Vc applied to the cylindrical electrode E3, which are required to efficiently transport the beam was 50 to 60 kV, in the conventional example illustrated in FIG. 1. On the other hand, in FIG. 4, when the voltage Vd applied by the separated high voltage power supply 22d is set to 30 kV, since the beam travels through an electrical environment which is at 30 kV in the electrostatic lenses 9a, 9b, the beam substractly as a 30 keV beam is effectively acted by the electrostatic lenses 9a, 9b. In the third embodiment illustrated in FIG. 4, the voltage applied to the cylindrical electrode E3 (anode) is sufficient to the required voltage that the beam at 30 keV can be transported, and it is, therefore, enough to be the above-mentioned required voltage plus the voltage added by the voltage applied to the common electrode portion 23. In fact, in the example of the third embodiment that the voltage at 30 kV is applied to the common electrode portion, the voltage applied to the cylindrical electrode E3 was enough less than 50 kV. Therefore, according to the present embodiment, it was confirmed that no abnormal discharge occurred in the electrostatic lenses 9a, 9b as well as in the extraction electrode 7, and the performance of a current and the shape of a beam were also obtained as same as the result of the examples of the first embodiment and second embodiment.

### Fourth Embodiment

In the first embodiment illustrated in FIG. 2, the second embodiment illustrated in FIG. 3 and the third embodiment illustrated in FIG. 4 of the present invention, it has been confirmed that micro-discharges were likely to occur in the small spaces between the peripheral portion and each of the first electrical connection member La, the second electrical connection member Lb and the third electrical connection member Lc (wiring or metal rod member 25) which are coupled each of the first high voltage introduction flange 20a, the second high voltage introduction flange 20b and the third high voltage introduction flange 20c to each of the ionizer 5 and the cylindrical electrodes E3, specifically between the wiring or metal rod member 25 and the inner edge E of the vacuum vessel 2. This is because, in the first to third embodiments, as mentioned above, the beams in the first electrostatic lens 9a and the second electrostatic lens 9b are transported as the beams which effectively correspond to the energy of low voltage, and therefore the beams tend to spread. The degree of spreading becomes small as the energy increases, when a value of current applied by a power source is same. In the conventional example illustrated in FIG. 1, when the voltage, for example, is set to 60 kV and applies to the ionizer 5, the ions are transported through the electrostatic lenses 9a, 9b while maintaining a high energy of 60 keV, and are irradiated onto the irradiated substrate 15 as the beam of 60 keV. On the other hand, in the examples of the first embodiment through the third embodiment, the high voltage Vd (30 kV, for example) generated from the separated high voltage power supply 22d is applied to the common electrode portion 23, when the applied voltage Va applied to the ionizer 5 is set to 30 kV, the beam of 60 keV is irradiated onto the irradiated substrate (ground potential) as well as the conventional example illustrated in FIG. 1. As a result, the beam is easier to collide with the electrodes (E1 through E3) or the like, and the secondary charged particles are easier to be emitted from the surface of the electrodes by the collisions. In addition, the lot of collisions between the beam and the residual gas (neutrals) tend to occur even in the peripheral spaces of the spread beam. Some of these charged particles tend to scatter into the surrounding space as well. It has been experimentally confirmed that micro discharges triggered by these charged particles between the inner surface of the vacuum vessel 2, particularly the edge portion E, and each of the first electrical connection member La, the second electrical connection member Lb and the third electrical connection member Lc (wiring or the metal rod member 25) and the anode rod 17 which applies the voltage to the ionizer 5. In addition, in the first embodiment through the third embodiment, it has been also confirmed from a beam trajectory calculation simulation that the beam tends to spread in the electrostatic lenses 9a, 9b.

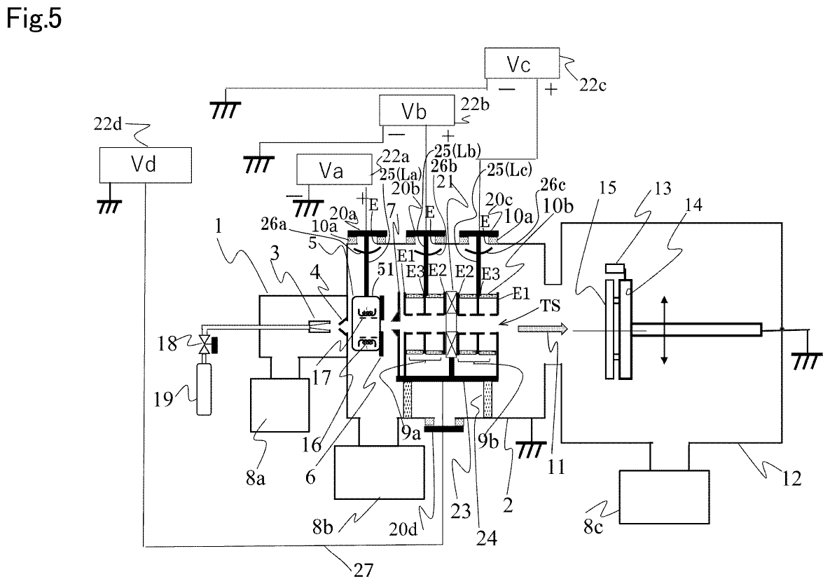

For the sake to resolve the above-mentioned problem, the fourth embodiment illustrated in FIG. 5 has been proposed. The fourth embodiment also uses same reference numerals as used in FIG. 1 and FIG. 2 for the components which are same or similar to the components used for the conventional GCIB apparatus illustrated in FIG. 1 and are same or similar to the components used for the first embodiment illustrated in FIG. 2. In the fourth embodiment, the first electrical connection member La, the second electrical connection member Lb and the third electrical connection member Lc that electrically couple the first high voltage introduction flange 20a, the second high voltage introduction flange 20b and the third high voltage introduction flange 20c to the ionizer 5 and the cylindrical electrode E3 (anode) are each made of metal rod member 25. In addition, each of metallic shielding members 26a, 26b and 26c, is respectively fixed to each of the three metallic rod members 25. The metallic shielding members 26a, 26b and 26c prevent the secondary charged particles (mainly electrons) from reaching the first high voltage introduction flange 20a, the second high voltage introduction flange 20b and the third high voltage introduction flange 20c. The secondary charged particles (mainly electrons) are generated by the above-mentioned beam divergence collisions from the electrodes or generated by the collisions between the gas cluster ion beam 11 and the gas molecules in the divergence periphery. Each of the shielding members 26a, 26b and 26c of the present embodiment has a curved shape of which a center is fixed to the metallic rod member 25 and that curves from the center toward the outside, so as to approach the corresponding high voltage introduction flange. It has been confirmed through experiments that the shielding members 26a, 26b and 26c mentioned above makes it possible to prevent micro-discharges between the three metallic rod members 25 which constitute the first electrical connection member La, the second electrical connection member Lb and the third electrical connection member Lc and the inner surface of the vacuum vessel 2 positioned close to the three metallic rod members 25. Thereby, it has been also confirmed that the extracted gas cluster ion beam 11 can be stably obtained. Note that if the shielding members 26a, 26b and 26c each adopt the curved shape, it has been also confirmed to effectively prevent the charged particles that induce micro-discharges from penetrating into the shielding members 26a, 26b and 26c. Note that it has been confirmed that the reduction of the micro-discharges by mounting the metallic shielding members 26a, 26b and 26c is effective even in the configurations in the first embodiment and the second embodiment.

In the above-mentioned embodiment, the first high voltage power supply to the third high voltage power supply are each explained as a separated high voltage power supply, but it goes without saying that one common high voltage power supply may be used.

### Effects of the Embodiments

According to the first embodiment to the fourth embodiment described above, gas cluster ions can be generated with the ionization by an electron beam impact, in which the cluster beam (neutral) is generated as a mass of which several hundred to several thousand or more of gas molecules and gas atoms was agglomerated by ejecting gas at a pressure of several to several tens of atmosphere through a thin nozzle into a vacuum. Then, the gas cluster ions are extracted by the extraction electrode 7 from the ionizer 5 at high voltage and become an ion beam. Thereafter, the gas cluster ion beam apparatus, that a beam can irradiate onto the irradiated substrate 15 through the beam transport system TS constituted by the electrostatic lenses 9a, 9b and the permanent magnet type magnet 21 which is a magnet field generating device, can be provided. According to the utilization of the apparatus of the present embodiment, etching with little damage or flattering of the surface roughness can be performed over the entire surface layer formed on the surface of the irradiated substrate 15 at the μm to mm level.

In addition, according to the present embodiment, it is possible to realize a GCIB apparatus that can easily obtain beams with different energies for a GCIB optimized for a specific acceleration voltage, without changing the distance between the acceleration electrode 6 and the extraction electrode 7 or the shape of the acceleration electrode 6 and the extraction electrode 7, and without changing the magnetic field strength of the magnet introduced in the beam transport system TS. Thereby, the gas cluster ion beam that is stable and efficient in the wide energy range (accelerating voltage range) can be irradiated. In addition, cluster ion beam irradiations with different energies onto the same irradiated substrate can be continuously carried out. For example, etching of a sample in a high voltage region is carried out, thereafter the irradiation with a low energy is added so that the gas cluster ion beam processing with high speed and flat can be carried out. As one area where the processing mentioned above is required, there is a surface treatment processing of piezoelectric element material. The apparatus of the present invention can provide a GCIB irradiation apparatus that can process with higher speed and few surface defects.

While the preferred embodiments of the invention have been described with a certain degree of particularity with reference to the drawings, obvious modifications and variations are possible in light of the above teachings. It is therefore to be understood that within the scope of the appended claims, the invention may be practiced other than as specifically described.

### INDUSTRIAL APPLICABILITY

According to the present invention, in the case that the separated high voltage power supply generates a positive or a negative high voltage, when the positive or negative high voltage is applied from the separated high voltage power supply to the ground electrode portion of the extraction electrode and the ground electrode portion of the one or more electrostatic lenses, the ion beam that is extracted from the ionizer can irradiate as the beam generated under the same voltage condition as when a positive or negative high voltage that is applied from the separated high voltage power supply is added to a positive high voltage that is applied from the high voltage power supply to the extraction electrode and one or more electrostatic lenses onto the irradiated substrate. As a result, it is possible to increase the energy of the irradiated ion beam by using the high voltage to which the positive high voltage applied from the separated high voltage power supply is added without changing the electrode arrangement of the GCIB apparatus and the magnetic field strength of the magnet, without changing the existing equipment.

1. A gas cluster ion beam apparatus, comprising:
a cluster generation chamber that generates a neutral gas cluster beam of gas atoms or gas molecules by injecting high-pressure gas through a nozzle in a vacuum,
a skimmer that skims a cluster beam from a central region in the neutral gas cluster beam,
an ionizer that generates cluster ions by impacting accelerated thermal electrons with the cluster beam introduced through the skimmer,
a beam transport system that extracts the cluster ions from the ionizer as a cluster ion beam by a potential difference between an acceleration electrode provided at the outlet of the ionizer and to which a positive high voltage is applied from a high voltage power supply, and an extraction electrode provided downstream of the acceleration electrode, and that irradiates the cluster ion beam onto an irradiated substrate placed in a vacuum vessel for an irradiation chamber through one or more electrostatic lenses to which the positive high voltage is applied from the high voltage power supply,
a permanent magnet type magnet that is included in the beam transport system and removes monomer ions,
a separated high voltage power supply that generates a positive or negative high voltage separately from the high voltage power supply, and
a separated high voltage application circuit that applies the positive or negative high voltage from the separated high voltage power supply to the ground electrode portion of the extraction electrode, the ground electrode portion of the one or more electrostatic lenses, and the negative terminal portion of the high voltage power supply.

2. A gas cluster ion beam apparatus, comprising:
a cluster generation chamber in which high-pressure gas is injected through a nozzle in a vacuum to generate a neutral gas cluster beam of gas atoms or molecules,
a skimmer that selects a cluster beam in a central region of the neutral gas cluster beam,
an ionizer that generates cluster ions by impact ionization of the cluster beam introduced through the skimmer with accelerated thermal electrons,
a beam transport system (TS) that extracts the cluster ions from the ionizer as a cluster ion beam by a potential difference between an acceleration electrode provided at the outlet of the ionizer and to which a positive high voltage is applied from a high voltage power supply whose negative terminal part is grounded, and an extraction electrode provided downstream of the acceleration electrode, and that irradiates the cluster ion beam onto an irradiated substrate placed in a vacuum vessel for irradiation chamber through one or more electrostatic lenses to which the positive high voltage is applied from the high voltage power supply whose negative terminal part is grounded,
a permanent magnet type magnet that is included in the beam transport system and removes monomer ions,
a separated high voltage power supply that generates a positive or negative high voltage separately from the high voltage power supply, and
a separated high voltage application circuit that applies the positive or negative high voltage from the separated high voltage power supply to the extraction electrode and the ground electrode portion of the one or more electrostatic lenses.

3. The gas cluster ion beam apparatus according to claim 1, wherein:
the separated high voltage application circuit includes a common electrode portion to which the ground electrode portion of the extraction electrode, the ground electrode portion of the one or more electrostatic lenses, and the ground electrode portion directly connected to the permanent magnet type magnet are electrically and mechanically connected in common.

4. The gas cluster ion beam apparatus according to claim 1, wherein:
the separated high voltage application circuit is electrically coupled to a common electrode portion to which the ground electrode portion of the extraction electrode, the ground electrode portion of the one or more electrostatic lenses, and the ground electrode portion directly connected to the permanent magnet type magnet are electrically or mechanically connected in common,
the common electrode portion is made of a metal one-piece electrode plate member,
the electrode plate member has a structure that mechanically supports the extraction electrode, the one or more electrostatic lenses and the permanent magnet type magnet, and
the electrode plate member is attached via an electrical insulator to a vacuum vessel in which at least the extraction electrode, the electrostatic lenses and the permanent magnet type magnet are stored.

5. The gas cluster ion beam apparatus according to claim 1, wherein:
the one or more electrostatic lenses comprise two Einzel lenses arranged in the direction in which the cluster ion beam passes,
the high voltage power supply includes a first high voltage power supply that applies the high voltage to the acceleration electrode, and a second high voltage power supply and a third high voltage power supply that apply high voltages to the two Einzel lenses constituting the one or more electrostatic lenses,
the permanent magnet type magnet is disposed between the two Einzel lenses,
the two Einzel lenses have two cylindrical ground electrodes at both ends of a central cylindrical electrode,
a positive high voltage applied from the separated high voltage power supply is applied to the two cylindrical ground electrodes,
the acceleration electrode is electrically coupled to the ionizer fixed to a first electrical connection member electrically coupled to a first high voltage introduction flange attached to the vacuum vessel, and
only the central cylindrical electrode of the two Einzel lenses is coupled to a second electrical connection member and a third electrical connection member which are electrically coupled to a second high voltage introduction flange and a third high voltage introduction flange attached to the vacuum vessel.

6. The gas cluster ion beam apparatus according to claim 5, wherein:
the first electrical connection member, the second electrical connection member and the third electrical connection member are each made of a metallic rod member, and
each of metallic shielding members, which prevent the charged particles generated from the cluster ion beam from reaching the first high voltage introduction flange, the second high voltage introduction flange and the third high voltage introduction flange, is fixed to each of the three metallic rod members that constitute the first electrical connection member, the second electrical connection member and the third electrical connection member.

7. The gas cluster ion beam apparatus according to claim 6, wherein:
each of the shielding members has a curved shape of which a center is fixed to the metallic rod member and that curves from the center toward the outside, so as to approach the corresponding high voltage introduction flange.

8. The gas cluster ion beam apparatus according to claim 1, wherein:
the separated high voltage power supply is a bipolar high voltage power supply that can generate both positive and negative outputs.

9. The gas cluster ion beam apparatus according to claim 1, wherein:
a central magnetic field strength of the permanent magnet type magnet is a value of 0.1 T or more, which causes a deflection to such an extent that SF6 monomer ions in the gas cluster beam containing SF6 extracted from the ionizer at an acceleration voltage of 30 KV do not reach the irradiated substrate.

10. The gas cluster ion beam apparatus according to claim 1, wherein:
the output voltage of the high voltage power supply and the output voltage of the separated high voltage power supply are equal, when the high voltage power supply outputs a positive voltage and the separated high voltage power supply applies the positive high voltage.

11. The gas cluster ion beam apparatus according to claim 2, wherein:
the output voltage of the high voltage power supply is higher than the output voltage of the separated high voltage power supply, when the high voltage power supply outputs a positive voltage and the separated high voltage power supply applies the positive high voltage.

12. The gas cluster ion beam apparatus according to claim 2, wherein:
the separated high voltage application circuit includes a common electrode portion to which the ground electrode portion of the extraction electrode, the ground electrode portion of the one or more electrostatic lenses, and the ground electrode portion directly connected to the permanent magnet type magnet are electrically and mechanically connected in common.

13. The gas cluster ion beam apparatus according to claim 2, wherein:
the separated high voltage application circuit is electrically coupled to a common electrode portion to which the ground electrode portion of the extraction electrode, the ground electrode portion of the one or more electrostatic lenses, and the ground electrode portion directly connected to the permanent magnet type magnet are electrically or mechanically connected in common,
the common electrode portion is made of a metal one-piece electrode plate member,
the electrode plate member has a structure that mechanically supports the extraction electrode, the one or more electrostatic lenses and the permanent magnet type magnet, and
the electrode plate member is attached via an electrical insulator to a vacuum vessel in which at least the extraction electrode, the electrostatic lenses and the permanent magnet type magnet are stored.

14. The gas cluster ion beam apparatus according to claim 2, wherein:
the one or more electrostatic lenses comprise two Einzel lenses arranged in the direction in which the cluster ion beam passes,
the high voltage power supply includes a first high voltage power supply that applies the high voltage to the acceleration electrode, and a second high voltage power supply and a third high voltage power supply that apply high voltages to the two Einzel lenses constituting the one or more electrostatic lenses,
the permanent magnet type magnet is disposed between the two Einzel lenses,
the two Einzel lenses have two cylindrical ground electrodes at both ends of a central cylindrical electrode,
a positive high voltage applied from the separated high voltage power supply is applied to the two cylindrical ground electrodes,
the acceleration electrode is electrically coupled to the ionizer fixed to a first electrical connection member electrically coupled to a first high voltage introduction flange attached to the vacuum vessel, and
only the central cylindrical electrode of the two Einzel lenses is coupled to a second electrical connection member and a third electrical connection member which are electrically coupled to a second high voltage introduction flange and a third high voltage introduction flange attached to the vacuum vessel.

15. The gas cluster ion beam apparatus according to claim 14, wherein:
the first electrical connection member, the second electrical connection member and the third electrical connection member are each made of a metallic rod member, and
each of metallic shielding members, which prevent the charged particles generated from the cluster ion beam from reaching the first high voltage introduction flange, the second high voltage introduction flange and the third high voltage introduction flange, is fixed to each of the three metallic rod members that constitute the first electrical connection member, the second electrical connection member and the third electrical connection member.

16. The gas cluster ion beam apparatus according to claim 15, wherein:
each of the shielding members has a curved shape of which a center is fixed to the metallic rod member and that curves from the center toward the outside, so as to approach the corresponding high voltage introduction flange.

17. The gas cluster ion beam apparatus according to claim 2, wherein:
the separated high voltage power supply is a bipolar high voltage power supply that can generate both positive and negative outputs.

18. The gas cluster ion beam apparatus according to claim 2, wherein:
a central magnetic field strength of the permanent magnet type magnet is a value of 0.1 T or more, which causes a deflection to such an extent that SF6 monomer ions in the gas cluster beam containing SF6 extracted from the ionizer at an acceleration voltage of 30 KV do not reach the irradiated substrate.
